(19) United States
(12) Patent Application Publication
(10) Pub. No.: US 2011/0188672 A1
(43) Pub. Date: Aug. 4, 2011

(54) ACOUSTIC REPRODUCTION DEVICE

(75) Inventors: Masaki Tada, Osaka (JP); Katsu Takeda, Osaka (JP); Masashi Minakuchi, Hyogo (JP); Fumiyasu Konno, Osaka (JP)

(73) Assignee: PANASONIC CORPORATION, Osaka (JP)

(21) Appl. No.: 13/058,060

(22) PCT Filed: Oct. 2, 2009
(86) PCT No.: PCT/JP2009/005095

§ 371 Date: Feb. 8, 2011

(30) Foreign Application Priority Data
Oct. 6, 2008 (JP) 2008-259243

(51) Int. Cl. H03G 5/00

(52) U.S. Cl. 381/98

(57) ABSTRACT

A sound reproduction apparatus reproduces a sound wave at a listening position. The sound reproduction apparatus includes a compensation processing unit for compensating an audible band signal having an audible band frequency, a carrier signal oscillator for generating a carrier signal, a modulator for outputting a modulated signal obtained by modulating the carrier signal based on the audible band signal compensated by the compensation processing unit, and a sound emission unit for outputting a sound wave depending on the modulated signal output from the modulator. The compensation processing unit compensates the audible band signal based on a distance from the sound emission unit to the listening position. This sound reproduction apparatus can reproduce the original audible band signal with a high fidelity regardless of the listening position.

### TECHNICAL FIELD

The present invention relates to a sound reproduction apparatus having a high directivity that emits an ultrasonic band signal as a carrier signal by modulating an audible band signal and that can reproduce an audible band sound wave in a specific space area.

### BACKGROUND ART

A sound reproduction apparatus can emit an audible band sound wave to a medium, such as air, via a diaphragm and can propagate the audible band sound wave by a diffractive effect in a wider area.

On the other hand, in order to selectively propagate an audible band sound wave only in a specific space area, a highly-directive sound reproduction apparatus has been put to practical use such as a super directive loudspeaker or a parametric loudspeaker. In this sound reproduction apparatus, an ultrasonic band signal as a carrier signal is modulated by an audible band signal and is amplified by a predetermined gain. Then, the amplified signal is input to a sound emission unit, such as an ultrasonic transducer, for generating ultrasonic waves. The sound emission unit emits the signal as an ultrasonic band sound wave into a medium, such as air.

The sound wave emitted from the sound emission unit propagates with a high directivity due to the propagation characteristic of the ultrasonic wave as a carrier signal. While propagating the medium, the ultrasonic band sound wave has an amplitude of an audible band sound wave accumulated due to a nonlinearity of the medium, and the ultrasonic band sound wave attenuates due to the absorption by the medium and a spherical diffusion. As a result, the audible band signal modulated to have an ultrasonic band is self-demodulated by the nonlinearity of the medium to the original audible band signal output from the audible band signal source. Thus, audible sound can be reproduced only within a limited narrow space area.

In the sound reproduction apparatus as described above, the audible band sound wave emitted from the sound emission unit and demodulated in the medium has a sound pressure that depends on the frequency. Thus, it is difficult to reproduce, with a high fidelity, the original audible band signal output from the audible band signal source. FIG. 10 illustrates frequency characteristic C101 of the sound pressure of an audible band sound wave output from the sound emission unit. FIG. 10 also illustrates frequency characteristic C102 that has a sound pressure not depending on the frequency and that has a fixed ideal sound pressure. The self-demodulated sound wave has a sound pressure that is proportional to the second order derivative of the amplitude of the original audible band signal. Thus, with regard to the audible band sound wave emitted from the sound emission unit and demodulated in the medium, the sound pressure in a low frequency band is lower than the sound pressure in a high frequency band. When the audible band signal includes various frequency components, the audible band sound wave emitted from the sound emission unit and demodulated in the medium has a sound pressure that varies depending on the frequency and that does not have ideal frequency characteristic C102. Thus, an audible band signal cannot be demodulated with a high fidelity.

FIG. 11 is a block diagram illustrating conventional sound reproduction apparatus 101 disclosed in Patent Literature 1. Sound reproduction apparatus 101 includes: audible band signal source 102; compensation processing unit 103 for compensating an audible band signal from audible band signal source 102; modulator 104 for modulating a carrier signal based on the signal compensated by compensation processing unit 103 to output a modulated signal; power amplifier 105 for amplifying the modulated signal from modulator 104; and sound emission unit 106 for outputting the signal amplified by power amplifier 105 to outside.

FIG. 12 illustrates frequency characteristics C101 and C102 of the sound pressure shown in FIG. 10 and compensation profile P101 obtained by the compensation by compensation processing unit 103 to an audible band signal. Compensation profile P101 has a characteristic reverse, up-and-down direction to frequency characteristic C101. As described above, compensation processing unit 103 compensates the amplitude of an audible band signal from the audible band signal source based on compensation profile P101 to output the compensated signal. As a result, an audible band signal having been emitted from the sound emission unit and self-modulated in the medium is reproduced.

However, sound reproduction apparatus 101 shown in FIG. 11 cannot demodulate, with a high fidelity, an audible band signal depending on a position.

### CITATION LIST

### Patent Literature

[Patent Literature 1] Japanese Patent Unexamined Publication No. 2004-328236

### SUMMARY OF THE INVENTION

A sound reproduction apparatus reproduces a sound wave at a listening position. The sound reproduction apparatus includes a compensation processing unit for compensating an audible band signal having an audible band frequency, a carrier signal oscillator for generating a carrier signal, a modulator for outputting a modulated signal obtained by modulating the carrier signal based on the audible band signal compensated by the compensation processing unit, and a sound emission unit for outputting a sound wave depending on the modulated signal output from the modulator. The compensation processing unit compensates the audible band signal based on a distance from the sound emission unit to the listening position.

This sound reproduction apparatus can reproduce the original audible band signal with a high fidelity regardless of the listening position.

### BRIEF DESCRIPTION OF THE DRAWINGS

FIG. 1A is a block diagram illustrating a sound reproduction apparatus of Exemplary Embodiment 1 of the present invention.

FIG. 1B is a schematic diagram illustrating a sound emission unit of the sound reproduction apparatus of Embodiment 1.

FIG. 2 illustrates a propagation characteristic of an audible band sound wave that is output from a conventional sound reproduction apparatus and that is self-demodulated.

FIG. 3 illustrates the frequency characteristic of the sound pressure of an audible band sound wave that is output from the sound reproduction apparatus of Embodiment 1 and that is self-demodulated.

FIG. 4 illustrates a compensation characteristic of a compensation processing unit of the sound reproduction apparatus of Embodiment 1.

FIG. 5 illustrates the propagation characteristic of a sound pressure that is output from the sound reproduction apparatus of Embodiment 1 and that is self-demodulated.

FIG. 6 illustrates the frequency characteristic of a sound pressure of the sound wave output from the sound reproduction apparatus of Embodiment 1 and that is self-demodulated.

FIG. 7 is a block diagram of the compensation processing unit of the sound reproduction apparatus of Embodiment 1.

FIG. 8 is a block diagram of a sound reproduction apparatus of Exemplary Embodiment 2 of the present invention.

FIG. 9 is a schematic diagram illustrating a distance measurement of the sound reproduction apparatus of Embodiment 2.

FIG. 10 illustrates the frequency characteristic of a sound pressure of a sound wave.

FIG. 11 is a block diagram of the conventional sound reproduction apparatus.

FIG. 12 illustrates the compensation characteristic of a compensation processing unit of the conventional sound reproduction apparatus.

### DETAILED DESCRIPTION OF PREFERRED EMBODIMENTS

### Exemplary Embodiment 1

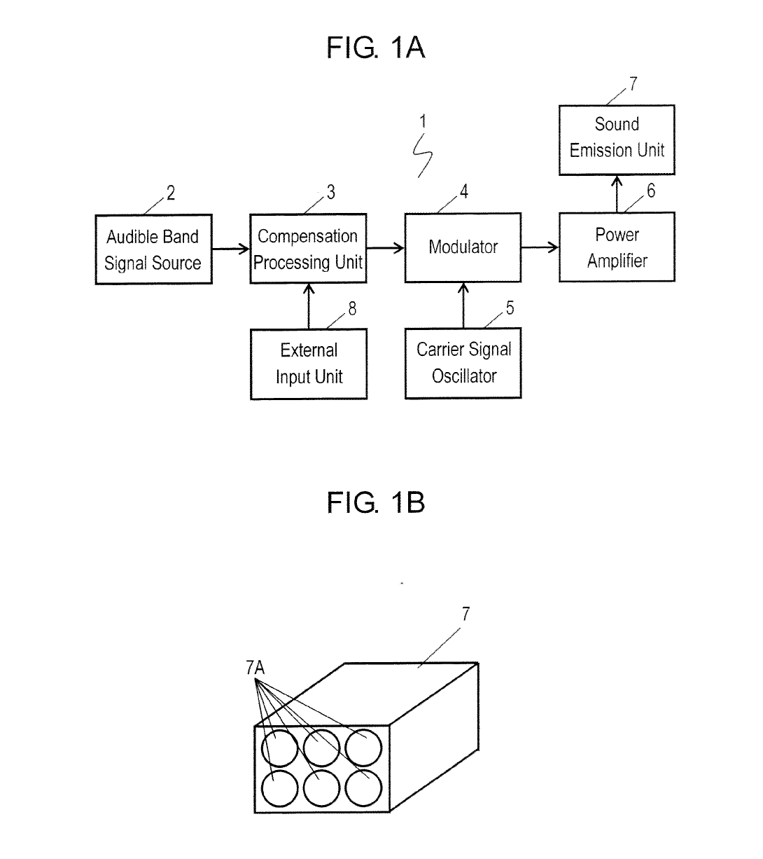

FIG. 1A is a block diagram illustrating sound reproduction apparatus 1 of Exemplary Embodiment 1 of the present invention. Audible band signal source 2 generates an audible band signal having an audible band frequency. The audible band generally ranges from 20 Hz to 20 kHz. Compensation processing unit 3 compensates the audible band signal. The signal compensated by compensation processing unit 3 is sent to modulator 4. Carrier signal oscillator 5 generates a carrier signal having a frequency higher than the highest frequency in the audible band. In Embodiment 1, the carrier signal has an ultrasonic band frequency higher than 20 kHz. Modulator 4 outputs a modulated signal obtained by amplitude-modulating the carrier signal based on the signal compensated by compensation processing unit 3. The modulated signal output from modulator 4 is amplified by power amplifier 6 and is sent to sound emission unit 7.

FIG. 1B is a schematic diagram of sound emission unit 7. Sound emission unit 7 is composed of ultrasonic transducers 7A. The signal sent from power amplifier 6 vibrates piezoelectric elements provided in ultrasonic transducer 7A to emit a sound wave, depending on the signal, to the medium, such as air. This sound wave is an ultrasonic wave that has a frequency of a carrier wave signal higher than the highest frequency of the audible band.

The sound wave emitted as an ultrasonic wave from sound emission unit 7 to the medium propagates through the medium with a high directivity that is the propagation characteristic of an ultrasonic wave. During the propagation of the ultrasonic band sound wave through the medium, the nonlinearity of the medium causes the amplitude of the audible band sound wave to be accumulated and increased. At the same time, the carrier wave signal of the frequency of the ultrasonic band attenuates due to an absorption by the medium and a spherical diffusion. As a result, the sound wave emitted from sound emission unit 7 is self-demodulated to a sound wave having an audible band frequency based on the audible band signal which has modulated the carrier wave signal.

As described above, sound reproduction apparatus 1 reproduces the audible band signal only at a limited specific position by using an ultrasonic wave having high directivity as a carrier signal to emit a sound wave through sound emission unit 7. When sound reproduction apparatus 1 is used as a loudspeaker to provide explanation in a picture gallery or a museum, sound can be transmitted only to a specific person.

Compensation processing unit 3 is connected to external input unit 8. A user operates external input unit 8 to manually set a distance from sound emission unit 7 to a listening position at which the sound wave is listened to.

Next, the following section will describe a method of compensating an audible band signal in compensation processing unit 3.

Generally, an audible band sound wave output from sound emission unit 7 and demodulated in a medium has a propagation characteristic varying depending on the frequency of the signal. Specifically, the audible band sound wave output from sound emission unit 7 and demodulated in the medium has a sound pressure varying depending on the frequency thereof and on a distance from sound emission unit 7 to a listening position at which the sound wave is listened to.

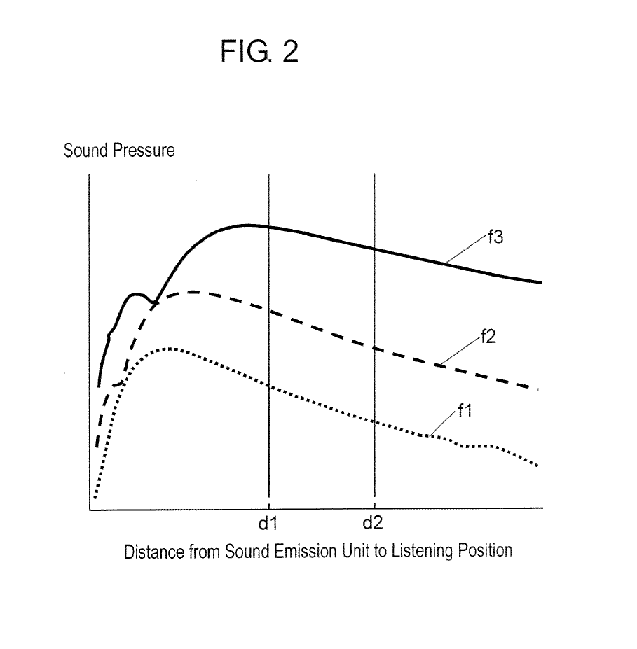

FIG. 2 illustrates the propagation characteristics of sound waves reproduced by sound emission unit 7 calculated based on the Khokhlov-Zabolotskaya-Kuznetsov (KZK) theoretical formula. In FIG. 2, the horizontal axis shows the distance from sound emission unit 7 to the listening position, and the vertical axis shows the sound pressure of the sound wave. As shown in FIG. 2, the sound wave shows different propagation characteristic profiles at frequency f1, frequency f2, and frequency f3 (f1<f2<f3). The sound pressure is also different, in the respective profiles (respective frequencies f1 to f3), depending on the distance from sound emission unit 7.

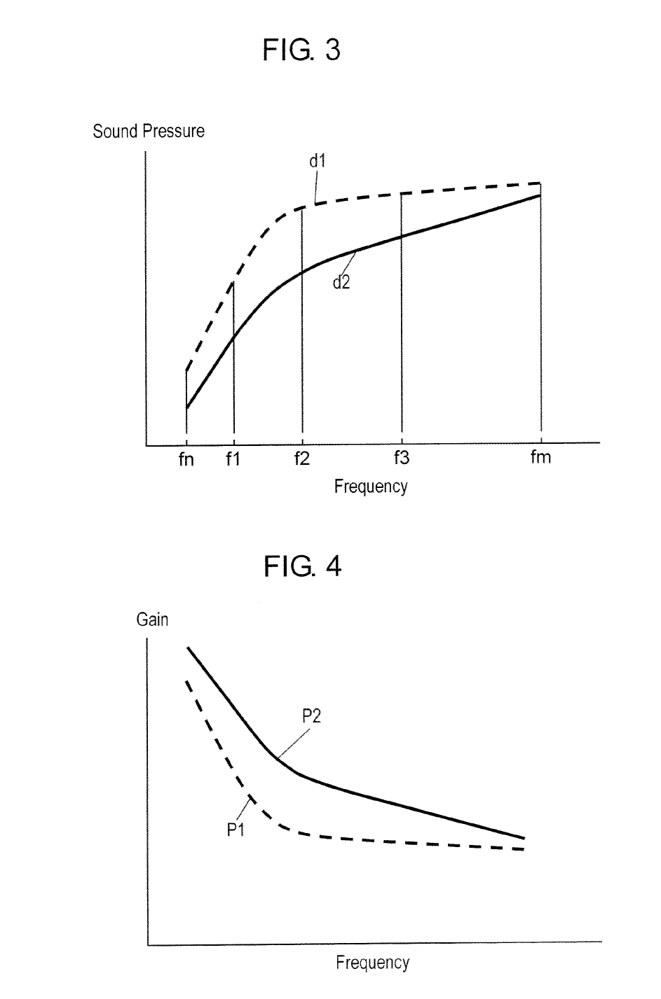

FIG. 3 illustrates the frequency characteristic of the sound pressure at listening distances of values d1 and d2 shown in FIG. 2. This frequency characteristic is calculated based on the KZK theoretical formula. In FIG. 3, the horizontal axis shows the frequency of the sound wave, and the vertical axis shows the sound pressure of the sound wave. Lowest frequency fn and highest frequency fm are the lowest frequency and the highest frequency among the frequency components of the sound waves emitted from sound emission unit 7. The sound pressure frequency characteristic shown in FIG. 3 corresponds to the sound pressure frequency characteristic of the audible band sound wave emitted from sound emission unit 7 and demodulated in the medium when sound reproduction apparatus 1 does not include compensation processing unit 3.

As shown in FIG. 3, in the case of an audible band sound wave emitted from sound emission unit 7 and demodulated in the medium, a sound pressure of a low frequency component is higher than a sound pressure of a high frequency component. The frequency characteristic is different at listening distances of values d1 and d2. That is, the sound pressure has a different frequency characteristic depending on the distance from sound emission unit 7 to the listening position.

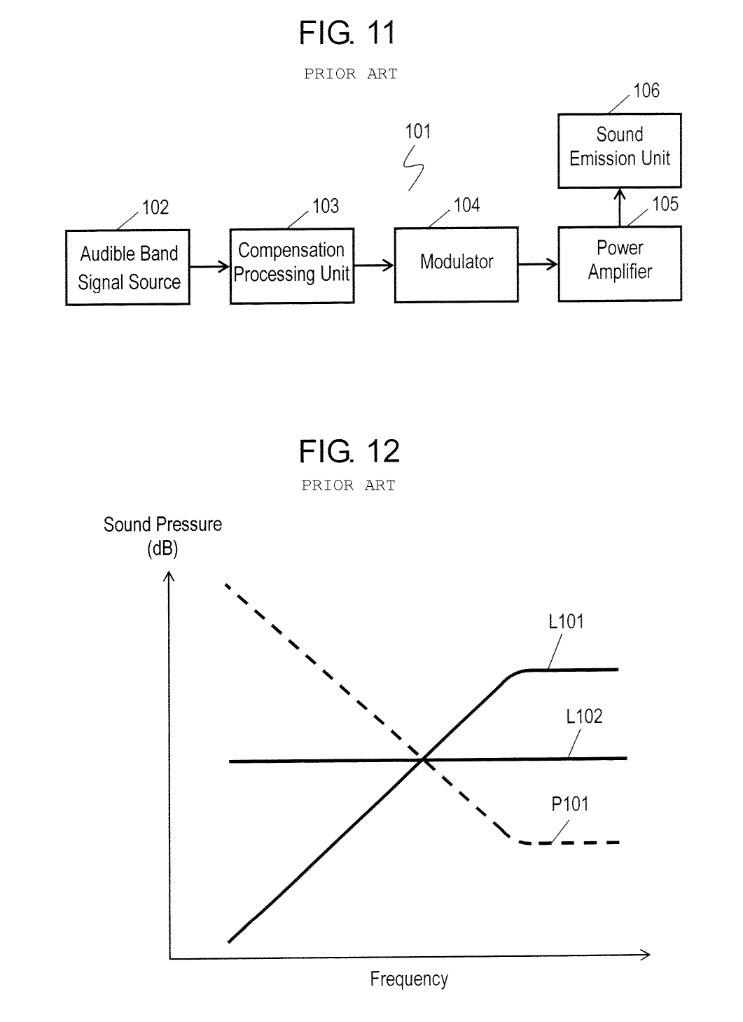

Conventional sound reproduction apparatus 101 shown in FIG. 11 outputs the same sound wave regardless of the distance from sound emission unit 107 to the listening position. Thus, some listening positions may make it difficult to demodulate the original audible band signal with a high fidelity.

In order to demodulate the original audible band signal at the listening positions at distance values d1 and d2 shown in FIG. 3 with a high fidelity, compensation processing unit 3 compensates the audible band signal depending on the frequency characteristic of the sound pressure of the self-demodulated audible band sound wave. FIG. 4 illustrates compensation profiles P1 and P2 that are stored in compensation processing unit 3 and that correspond to values d1 and d2 of the listening distance, respectively

Compensation profiles P1 and P2 are derived by the method described below. First, the frequency characteristics of the sound pressure of the self-demodulated audible band sound wave are calculated based on the KZK theoretical formula at listening distance values d1 and d2 from sound emission unit 7 to the listening position of the user. Then, compensation profiles P1 and P2 are prepared so as to have frequency characteristics reverse to the calculated frequency characteristics. Specifically, compensation profiles P1 and P2 have frequency characteristics reverse to the frequency characteristics of the sound pressure of the sound wave having an audible band frequency output from sound emission unit 7 depending on a signal not compensated by compensation processing unit 3, respectively. The term “frequency characteristic reverse to” means a frequency characteristic obtained by inverting, in the direction of the vertical axis, the graph of the frequency characteristic in which the vertical axis shows the sound pressure and the horizontal axis shows the frequency. Specifically, compensation profiles P1 and P2 shown in FIG. 4 have such a shape that is obtained by inverting, in the direction of the vertical axis, the frequency characteristic of the sound pressure of the sound wave at distance values d1 and d2 from sound emission unit 7 shown in FIG. 3 to the listening position. In Embodiment 1, compensation profiles P1 and P2 are calculated based on the KZK theoretical formula. Alternatively, compensation profiles P1 and P2 also may be calculated based on an approximation formula similar to the KZK theoretical formula or an actual measurement value. When compensation profiles P1 and P2 are calculated based on an actual measurement value, compensation profiles P1 and P2 can be an accurate profile suitable for an actual use.

As described above, compensation processing unit 3 of sound reproduction apparatus 1 of Embodiment 1 stores values d1 and d2 of the distance from sound emission unit 7 to the listening position and compensation profiles P1 and P2 corresponding to values d1 and d2, respectively. As a result, compensation processing unit 3 can select, from among the compensation profiles, an optimal compensation profile depending on various listening positions. Then, the selected compensation profile can be used to compensate an audible band signal, thereby demodulating the audible band signal to the original audible band signal with a high fidelity. It is noted that the number of the values of the distance from the listening position is not limited to two, and may be an arbitrary number not smaller than 3. Compensation processing unit 3 stores the compensation profiles corresponding to the values of the distance, respectively.

The following section will describe an operation of sound reproduction apparatus 1 when the distance from sound emission unit 7 to the listening position has value d1.

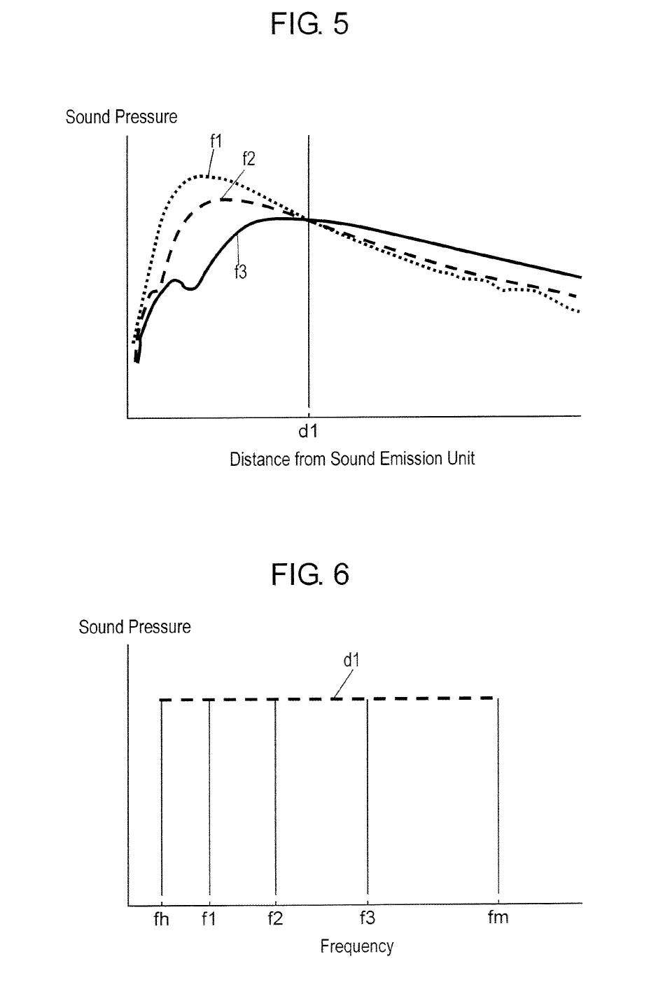

FIG. 5 illustrates the frequency characteristic of the sound pressure of the sound wave at the listening position when the distance from sound emission unit 7 of sound reproduction apparatus 1 to the listening position has value d1. Since the distance has value d1, compensation processing unit 3 compensates an audible band signal by compensation profile P1. That is, the gain of compensation processing unit 3 for the component of frequency f1 of the audible band signal is higher than the gain for the component of frequency f3. As a result, at the listening position at value d1 of the distance, the sound pressures of the components frequency f1 and frequency f3 can be equal to the sound pressure of the component of frequency f2. As a result, the audible band sound wave output from sound emission unit 7 and demodulated in the medium can have a sound pressure of a frequency characteristic that is flat at the distance of value d1 as in the ideal frequency characteristic shown in FIG. 6. Thus, the audible band signal output from audible band signal source 2 can be demodulated to the original audible band signal with a high fidelity.

Similarly, when the distance from sound emission unit 7 to the listening position has value d2, compensation processing unit 3 compensates the audible band signal based on compensation profile P2 in the same manner as described above. As a result, at the listening position at the distance of value d2, the audible band signal output from audible band signal source 2 can be demodulated with a high fidelity.

In sound reproduction apparatus 1 of Embodiment 1, the sound pressures of the components of frequency f1 and frequency f3 are equal to the sound pressure of the component of frequency f2. However, the present invention is not limited to this. The sound pressures of the components of frequencies f1 to f3 may be equal to the sound pressure of the component of frequency f1 or the component of frequency f3. Alternatively, the sound pressures of the components of frequencies f1 to f3 may be equal to any sound pressure other than the sound pressures of the components of frequencies f1 to f3.

Compensation processing unit 3 stores the values of the distance from sound emission unit 7 to the listening position and the compensation profiles corresponding to these values, respectively, as a compensation table. In sound reproduction apparatus 1, the values of the distance from sound emission unit 7 to the listening position is set by external input unit 8. Compensation processing unit 3 refers to the compensation table to uniquely select, from among the stored compensation profiles, a compensation profile that corresponds to the set value. Then, the compensation processing unit 3 compensates, based on the selected compensation profile, the amplitude of the audible band signal sent from audible band signal source 2.

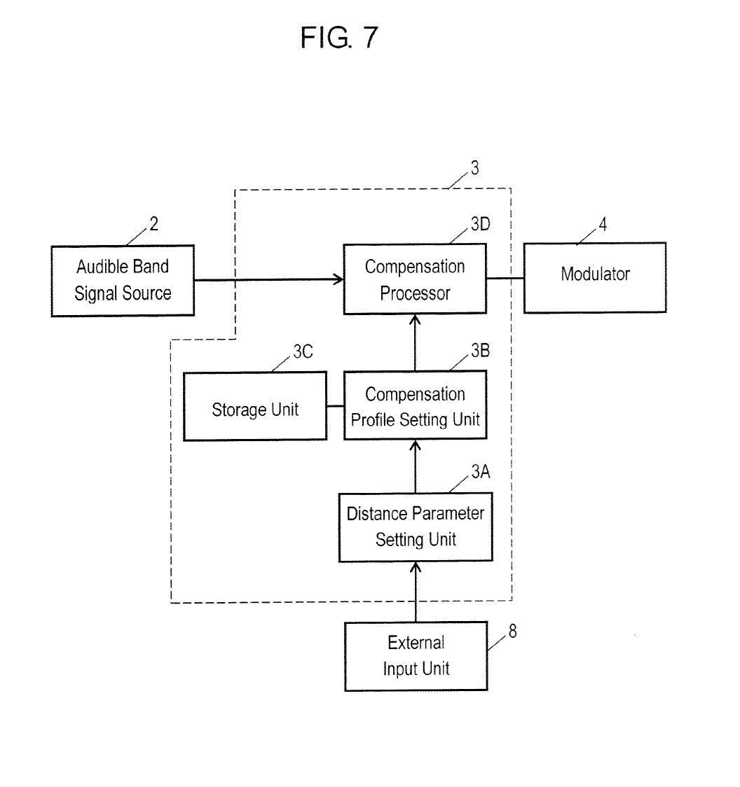

Next, the following section will describe the operation of compensation processing unit 3 in detail. FIG. 7 is a block diagram of compensation processing unit 3. Compensation processing unit 3 includes: distance parameter setting unit 3A; compensation profile setting unit 3B; storage unit 3C connected to compensation profile setting unit 3B; and compensation processor 3D. Distance parameter setting unit 3A is connected to external input unit 8. Compensation processor 3D is connected to audible band signal source 2 and modulator 4.

The value of the distance from sound emission unit 7 to the listening position is set with external input unit 8, the set value is input as a signal to distance parameter setting unit 3A. Upon receiving the signal from external input unit 8, distance parameter setting unit 3A selects a value corresponding to the input signal from among the number n of values d1 to dn. Then, distance parameter setting unit 3A sends the selected value as a signal to compensation profile setting unit 3B. Based on the sent signal, compensation profile setting unit 3B selects a compensation profile corresponding to the selected value from among compensation profiles P1 to Pn in the compensation table stored in storage unit 3C. Compensation processor 3D compensates, based on the compensation profile selected by compensation profile setting unit 3B, the amplitude of the audible band signal sent from audible band signal source 2 to send the compensated signal to modulator 4.

As described above, the user of sound reproduction apparatus 1 uses external input unit 8 to set the distance from sound emission unit 7 to the listening position, and can listen to a sound wave obtained by demodulating, at an arbitrary listening position, the audible band signal to the original audible band signal with a high fidelity.

### Exemplary Embodiment 2

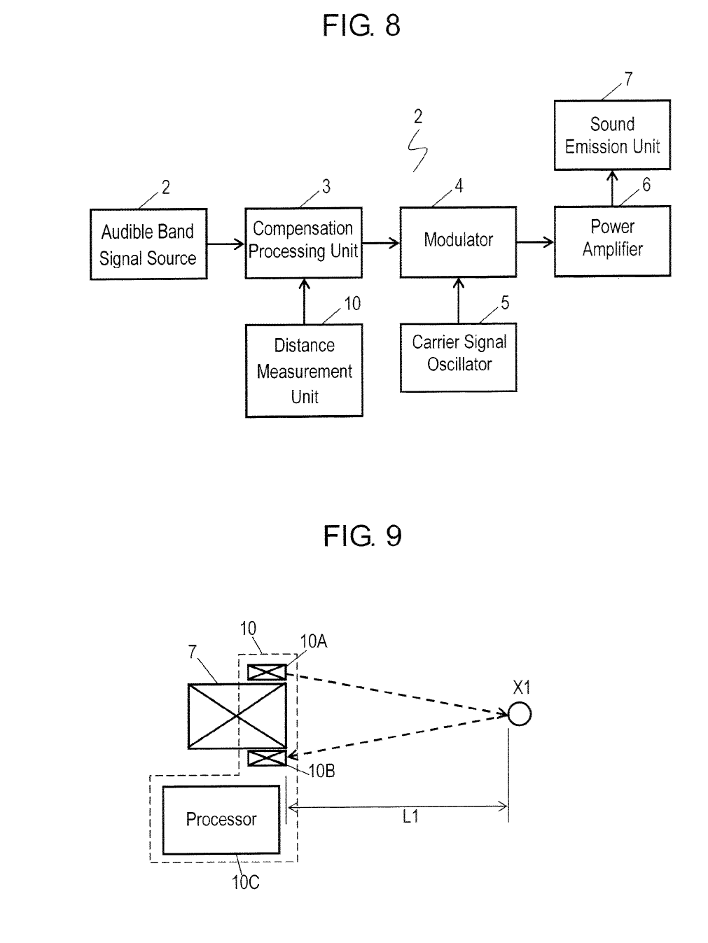

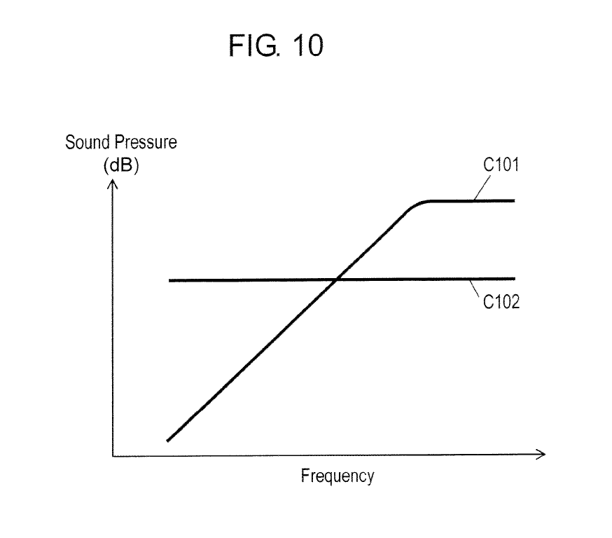

FIG. 8 is a block diagram illustrating sound reproduction apparatus 9 of Exemplary Embodiment 2 of the present invention. In FIG. 8, the same components as those of sound reproduction apparatus 1 of Embodiment 1 of FIG. 1A are denoted by the same reference numerals. Sound reproduction apparatus 9 in Embodiment 2 includes distance measurement unit 10 instead of external input unit 8 of sound reproduction apparatus 1 of Embodiment 1 shown in FIG. 1A. In sound reproduction apparatus 9, compensation processing unit 3 is connected to distance measurement unit 10. Distance measurement unit 10 measures the distance from sound emission unit 7 to listening position.

FIG. 9 is a schematic diagram of distance measurement unit 10. Distance measurement unit 10 includes: ultrasonic generator 10A for generating an ultrasonic wave; ultrasonic sensor 10B for receiving an ultrasonic wave; and processor 10C. The ultrasonic wave sent from ultrasonic generator 10A reaches a user located at listening position X1, is reflected by the user, and is then received by ultrasonic sensor 10B. Processor 10C measures the time lapsing from the transmitting of an ultrasonic wave by ultrasonic generator 10A to the receiving of the ultrasonic wave by the ultrasonic sensor. Based on the measured time, processor 10C calculates the value of distance L1 from sound emission unit 7 to listening position X1. Here, each of ultrasonic generator 10A and ultrasonic sensor 10B is composed of two independent ultrasonic transducers. Alternatively, ultrasonic generator 10A may be composed by an ultrasonic transducer, and ultrasonic sensor 10B may be implemented commonly by the ultrasonic transducer of ultrasonic generator 10A.

Distance measurement unit 10 may be implemented by a sensor utilizing, for example, light other than ultrasonic wave. However, distance measurement unit 10 may desirably use an ultrasonic wave. As shown in FIG. 1B, sound emission unit 7 is composed of ultrasonic transducers 7A. Some of ultrasonic transducers 7A of sound emission unit 7 can be used as ultrasonic generator 10A and ultrasonic sensor 10B. In this case, distance L1 from sound emission unit 7 to listening position X1 is equal to the distance from distance measurement unit 10 to listening position X1, hence allowing distance measurement unit 10 to accurately measure the value of distance L1.

The value of distance L1 from sound emission unit 7 to listening position X1 measured by distance measurement unit 10 is input as a signal to compensation processing unit 3.

As in sound reproduction apparatus 1 of Embodiment 1, compensation processing unit 3 uniquely selects, based on the measured value, a compensation profile from among compensation profiles P1 to Pn. Based on the selected compensation profile, compensation processing unit 3 compensates the amplitude of the audible band signal sent from audible band signal source 2. As a result, sound reproduction apparatus 9 can demodulate, at an arbitrary listening position, the audible band signal output from audible band signal source 2 to the original audible band signal with a high fidelity.

Sound reproduction apparatus 9 of Embodiment 2 includes distance measurement unit 10. Thus, even without a need for a user to manually set the value of the distance from sound emission unit 7 to the listening position, the same effect by sound reproduction apparatus 1 of Embodiment 1 can be obtained to thereby provide user friendliness.

In Embodiments 1 and 2, values d1 to do of distance L1 are not generally limited to a value represented by a unit of a distance, and also may be another value corresponding the distance.

### INDUSTRIAL APPLICABILITY

A sound reproduction apparatus according to the present invention is suitable as a highly-directive sound reproduction apparatus that can reproduce, regardless of a listening position, an audible band signal with a high fidelity and that can reproduce the sound of the audible band only within a limited space area.

### REFERENCE MARKS IN THE DRAWINGS

1 Sound reproduction apparatus

2 Audible band signal source

3 Compensation processing unit

3B Compensation profile setting unit

3C Storage unit

3D Compensation processor

4 Modulator

5 Carrier signal oscillator

7 Sound emission unit

9 Sound reproduction apparatus

10 Distance measurement unit

10A Ultrasonic generator

10B Ultrasonic sensor

1. A sound reproduction apparatus for reproducing a sound wave at a listening position, said sound reproduction apparatus comprising:
a compensation processing unit for compensating an audible band signal having an audible band frequency;
a carrier signal oscillator for generating a carrier signal;
a modulator for outputting a modulated signal obtained by modulating the carrier signal based on the audible band signal compensated by the compensation processing unit; and
a sound emission unit for outputting a sound wave depending on the modulated signal output from the modulator, wherein
the compensation processing unit compensates the audible band signal based on a distance from the sound emission unit to the listening position and
the compensation processing unit includes
a storage unit for storing a plurality of values of the distance and a plurality of compensation profiles corresponding to the plurality of values, respectively,
a compensation profile setting unit for uniquely selecting a compensation profile from among the plurality of compensation profiles based on a value of the distance from the sound emission unit to the listening position, and
a compensation processor for compensating the audible band signal based on the selected compensation profile.

2. (canceled)

3. The sound reproduction apparatus according to claim 1, wherein each of the plurality of compensation profiles has a frequency characteristic reverse to a frequency characteristic of a sound pressure of a sound wave having an audible band frequency output from the sound emission unit depending on a signal which is not compensated by the compensation processing unit.

4. The sound reproduction apparatus according to claim 3, wherein the frequency characteristic of the sound pressure of the sound wave is a characteristic calculated based on an actual measurement.

5. The sound reproduction apparatus according to claim 1, further comprising a distance measurement unit for measuring the distance from the sound emission unit to the listening position.

6. The sound reproduction apparatus according to claim 5, wherein the distance measurement unit includes
an ultrasonic generator for generating an ultrasonic wave, and
an ultrasonic sensor for receiving the generated ultrasonic wave.
